(19) United States
(12) Patent Application Publication
(10) Pub. No.: US 2026/0190885 A1
(43) Pub. Date: Jul. 2, 2026

(54) ETCH WITH SULFUR BASED OXYGEN FREE PASSIVANT

(71) Applicant: Lam Research Corporation, Fremont, CA (US)

(72) Inventors: Eric HUDSON, Berkeley, CA (US); Prabhat KUMAR, Fremont, CA (US)

(21) Appl. No.: 19/131,709

(22) PCT Filed: Nov. 27, 2023
(86) PCT No.: PCT/US2023/081180

§ 371 Date: May 21, 2025

Related U.S. Application Data
(60) Provisional application No. 63/430,744, filed on Dec. 7, 2022.

(51) Int. Cl. H10P 50/28; H10P 34/00

(52) U.S. Cl. CPC H10P 50/283; H10P 34/00

(57) ABSTRACT

A method for selectively etching a dielectric material with respect to a semiconductor material is provided. The dielectric material is etched. The semiconductor material is passivated by providing a passivation gas comprising a non-thiol sulfur based component, wherein the non-thiol sulfur based component is oxygen free.

### CROSS-REFERENCE TO RELATED APPLICATION

This application claims the benefit of priority of U.S. Application No. 63/430,744, filed Dec. 7, 2022, which is incorporated herein by reference for all purposes.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

In forming semiconductor devices, a dielectric layer may be selectively etched with respect to a semiconductor layer in order to form semiconductor devices. Some dielectric layers may be silicon oxide (SiO₂) based material or silicon nitride (SiN) based material. Dielectric materials are materials with high electrical resistance. Some semiconductor layers may be silicon (Si) layers, germanium (Ge) layers, or silicon germanium (SiGe) layers. Semiconductor materials are materials with an electrical conductivity between the electrical conductivity of electrical conductors and the electrical conductivity of dielectric or insulator materials.

### SUMMARY

To achieve the foregoing and in accordance with the purpose of the present disclosure, a method for selectively etching a dielectric material with respect to a semiconductor material is provided. The dielectric material is etched. The semiconductor material is passivated by providing a passivation gas comprising a non-thiol sulfur based component, wherein the non-thiol sulfur based component is oxygen free.

These and other features of the present disclosure will be described in more detail below in the detailed description and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of an embodiment.

FIGS. 2A-D are schematic views of a stack processed according to some embodiments.

FIG. 3 is a schematic view of a semiconductor processing chamber that may be used in some embodiments.

FIG. 4 is a schematic view of a computer system that may be used in practicing some embodiments.

In the drawings, like reference numerals are sometimes used to designate like structural elements. It should also be appreciated that the depictions in the figures are diagrammatic and not to scale.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well known process steps and/or structures have not been described in detail in order to not unnecessarily obscure the present disclosure.

Some etch technology relies on fluorocarbon and/or hydrofluorocarbon to provide a selective etch of SiO₂ or SiN based dielectric materials while protecting underlying epitaxial layers of semiconductor materials, such as Si, SiGe, and Ge. This approach generally does not provide a sufficient process window to control both the semiconductor material loss and robust etch (with good contact resistance and low incidence of features that are not sufficiently etched. Carbon-based passivation methods tend to consume a few nanometers (nm) of the semiconductor material before offering sufficient protection against etching. Increasing carbon deposition might reduce semiconductor loss but tends to increase the incidence of poor contact resistance and/or not-opens.

Alternative passivation using carbonyl sulfide (COS) as an etch additive shows some improvement but is still not sufficient to meet the needs of advanced nodes. This is attributed to the oxidation of semiconductor materials due to oxygen in the COS molecule.

Some embodiments introduce sulfur-based passivation in a form that avoids oxidation of semiconductor materials. In some embodiments, this is achieved by avoiding the presence of oxygen in the passivation molecules. In some embodiments, the affinity of the sulfur atom for Si and Ge promotes rapid passivation when these films are exposed during the etching of silicon oxide or silicon nitride resulting in less loss of semiconductor material. Furthermore, sulfur-based passivation is less likely to cause poor contact resistance and/or increased incidence of not-opens, compared to carbon-based passivation. In some embodiments, the sulfur passivant may form an electrically conductive carbon polysulfide polymer.

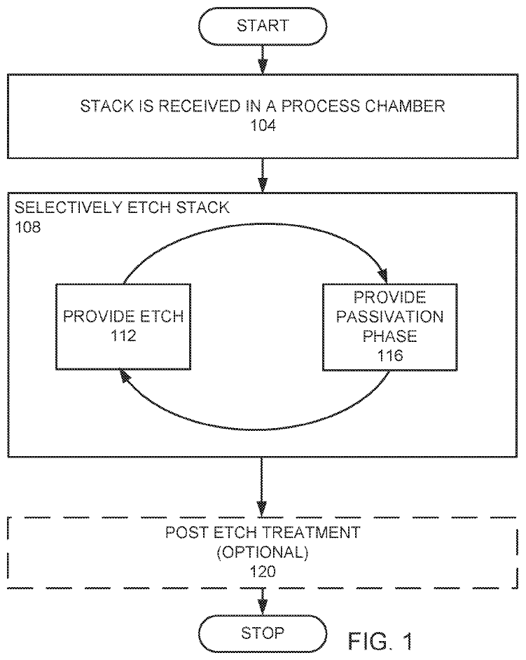

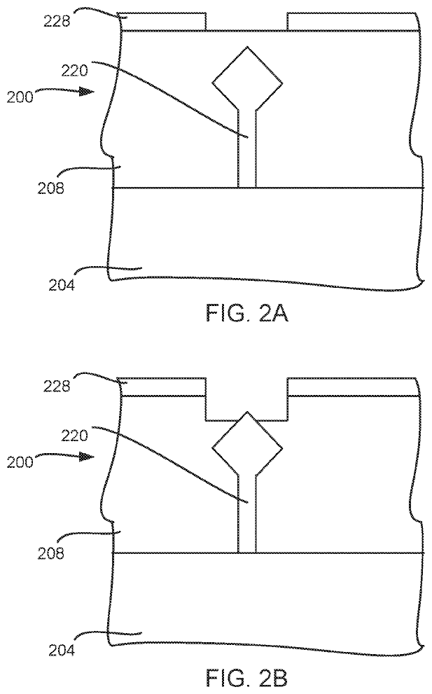

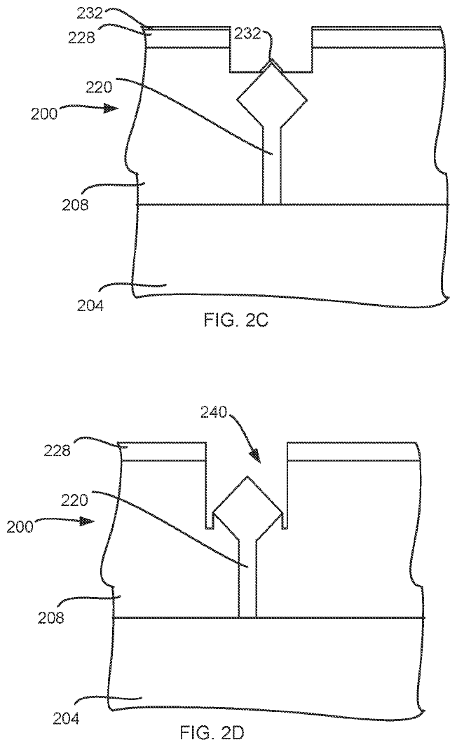

To facilitate understanding, FIG. 1 is a high level flow chart of a process used in some embodiments. In some embodiments, a stack is placed in an etch chamber (step 104). FIG. 2A is a cross-sectional view of a stack 200 that may be processed in some embodiments. The stack 200 includes a substrate 204 located under a dielectric layer 208. The dielectric layer 208 includes a fin field-effect transistor (FinFET) structure 220. In some embodiments, the dielectric layer 208 is a SiN based or SiO₂ based layer. A SiN based or SiO₂ based layer is made of a pure SiN or SiO₂ material or a material that is mostly SiN or SiO by weight and may have a dopant. The FinFET structure 220 is of a semiconductor material, such as either SiGe or Si or a combination thereof. SiGe or Si includes doped and undoped SiGe or Si. The top of the FinFET structure 220 has been enlarged using epitaxy forming an epitaxial layer 224. The stack 200 further includes a metal containing layer 228. The metal containing layer is formed over the dielectric layer 208 to act as an etch mask. In some embodiments, the metal containing layer 228 is tungsten carbide.

The dielectric layer 208 of the stack 200 is selectively etched with respect to the semiconductor material (step 108). In some embodiments, the selective etch may comprise a cyclical process of the steps of providing a dielectric layer etch phase (step 112) and the semiconductor material passivation phase (step 116) at different times. In some embodiments, the different times may overlap. In some embodiments, the different times do not overlap. In some embodiments, the dielectric layer etch phase (step 112) may be one or more of an atomic layer etch (ALE), a reactive ion etch (RIE), or a thermal etch. FIG. 2B is a cross-sectional view of a stack 200 after the dielectric layer phase 208 has been partially etched, exposing some of the semiconductor material forming the FinFET structure 220.

A passivation phase is provided (step 116) to passivate the semiconductor material of the exposed part of the FinFET structure 220. In some embodiments, a passivation gas comprising a non-thiol sulfur based component, where the non-thiol sulfur based component is oxygen free, is provided. In some embodiments, all of the passivation gas including the non-thiol sulfur based component is oxygen free. In some embodiments, the passivation gas provides passivation, so that in some embodiments, the passivation phase is a plasma free process. In some embodiments, the passivation gas is formed into a plasma, where the plasma provides passivation. In some embodiments, the passivation gas comprises hydrogen sulfide (H₂S). In some embodiments, the metal containing layer 228 is also passivated. FIG. 2C is a cross-sectional view of a stack 200 after the semiconductor of the exposed part of the FinFET structure 220 and the metal containing layer 228 have been passivated with a passivation layer 232.

The cycles of providing a dielectric layer etch phase (step 112) and a passivation phase (step 116) are repeated a plurality of times until the desired etch is completed. FIG. 2D is a cross-sectional view of a stack 200 after the etch of the dielectric layer phase 208 has been completed. A feature 240 has been etched into the dielectric layer 208 with minimal etching of the semiconductor finFET structure 220.

In some embodiments, an optional post etch treatment is provided (step 120). In some embodiments, the post etch process removes etch residue. In some embodiments, the removed etch residue is a remaining passivation layer. In some embodiments, the etch residue is at least one of etch contaminants and etch mask. In some embodiments, the post etch process is a stripping process. In some embodiments, other post etch processes may be performed, such as a plasma process that may be performed in the same chamber or a wet clean that may be performed in another chamber.

In some embodiments, the sulfur passivant reduces or eliminates etching of the semiconductor material. In some embodiments, the absence of oxygen in the passivant reduces or eliminates the oxidation of the semiconductor material. The use of sulfur as a passivant instead of carbon allows for an improved electrical connection with the semiconductor material.

In some embodiments, other non-thiol sulfur-based chemicals, that do not contain oxygen, are used as an additive to etch process. Thiol is a molecule in a class of organic molecules that are similar to alcohols and phenols but contain a sulfur atom in place of an oxygen atom. A thiol molecule would be a molecule in the form R—S—H, where R is an alkyl or other organic molecule. Non-thiol sulfur-based molecules would have sulfur but would not be in the form R—S—H, where R is an organic molecule. These non-thiol sulfur-based compounds include carbon disulfide (CS₂), cyanogen isothiocyanate (C₂N₂S), dimethyl sulfide (S(CH₃)₂), and other compounds based on sulfur combined with carbon. Using H₂S as a passivant provides a carbon free passivation gas, providing an advantage of being carbon free. In some embodiments, the passivant further comprises nitrogen gas (N₂). The addition of N₂ promotes the formation of polythiazyl (SN)ₓ, where x is an integer and where polythiazyl acts as a passivant. In some embodiments, the passivation gas further comprises at least one of hydrogen gas (H₂), N₂, a hydrocarbon, and a hydrofluorocarbon. Thiols may be needed for passivation in plasma processes. It was unexpectedly found that non-thiol sulfur-based chemicals that do not contain oxygen provide improved passivation in a thermal process that is plasma free. It was unexpectedly found that H₂S provides an improved passivation in a thermal process that is plasma free.

In some embodiments, the dielectric layer etch phase (step 112) and the semiconductor material passivation phase (step 116) are performed simultaneously. In some embodiments, the dielectric layer etch phase (step 112) and the semiconductor material passivation phase (step 116) are simultaneously performed in a single step to both etch the dielectric layer and passivate the semiconductor material.

In some embodiments, the semiconductor material is deposited by epitaxial deposition. Epitaxial deposition is a deposition process that deposits crystalline layers that are oriented with a seed layer. An example of epitaxial deposition is molecular-beam epitaxy. In some embodiments, the semiconductor material is crystalline. In some embodiments, the semiconductor material is amorphous or multicrystilline. In some embodiments, the semiconductor material is at least one of silicon, germanium, and silicon germanium. In some embodiments, the semiconductor material is doped. In some embodiments, the semiconductor material is not doped.

In some embodiments, the etch process is a cyclical etch process, such as atomic layer etching. In some embodiments, the etch process is a continuous etch process.

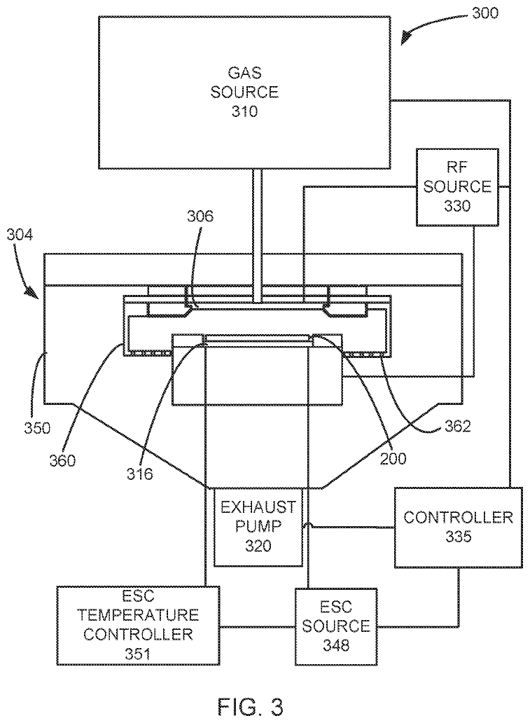

FIG. 3 is a schematic view of a etch chamber 300 for plasma processing substrates, in some embodiments. In some embodiments, the etch chamber 300 comprises a gas distribution plate 306 providing a gas inlet and an electrostatic chuck (ESC) 316, within a etch chamber 304, enclosed by a chamber wall 350. Within the etch chamber 304, the stack 200 is positioned on top of the ESC 316. The ESC 316 may provide a bias from an ESC power source 348. A gas source 310 is connected to the etch chamber 304 through the gas distribution plate 306. An ESC temperature controller 351 is connected to the ESC 316 and provides temperature control of the ESC 316. A radio frequency (RF) power source 330 provides RF power to the ESC 316 and an upper electrode. In this embodiment, the upper electrode is the gas distribution plate 306. In a preferred embodiment, 400 kilohertz (kHz), 13.56 megahertz (MHz), 1 MHz, 2 MHz, 60 MHz, and/or optionally, 27 MHz power sources make up the RF power source 330 and the ESC power source 348. A controller 335 is controllably connected to the RF power source 330, the ESC power source 348, an exhaust pump 320, and the gas source 310. A high flow liner 360 is a liner within the etch chamber 304, which confines gas from the gas source and has slots 362. The slots 362 maintain a controlled flow of gas to pass from the gas source 310 to the exhaust pump 320. An example of such a etch chamber is the Flex® etch system manufactured by Lam Research Corporation of Fremont, CA. The process chamber can be a CCP (capacitively coupled plasma) reactor or an ICP (inductively coupled plasma) reactor.

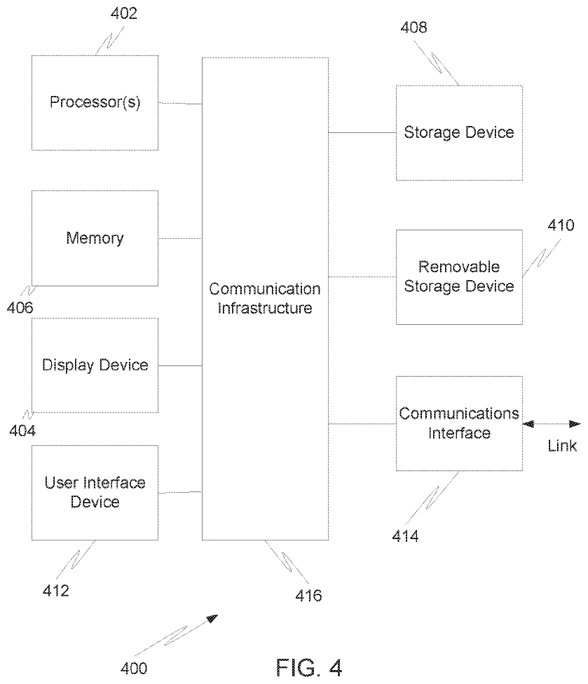

FIG. 4 is a high level block diagram illustrating a computer system 400 for implementing the controller 335 used in embodiments of the present inventions. The computer system may have many physical forms ranging from an integrated circuit, a printed circuit board, and a small handheld device up to a huge supercomputer. The computer system 400 may include one or more processors 402, and further can include an electronic display device 404 (for displaying graphics, text, and other data), a main memory 406 (e.g., random access memory (RAM)), storage device 408 (e.g., hard disk drive), removable storage device 410 (e.g., optical disk drive), user interface devices 412 (e.g., keyboards, touch screens, keypads, mice or other pointing devices, etc.), and/or a communication interface 414 (e.g., wireless network interface). The communication interface 414 may allow software and/or data to be transferred between the computer system 400 and external devices via a link. The system may also include a communications infrastructure 416 (e.g., a communications bus, cross-over bar, or network) to which the aforementioned devices/modules may be connected.

The information transferred via communications interface 414 may be in the form of signals such as electronic, electromagnetic, optical, or other signals capable of being received by communications interface 414, via a communication link that carries signals and may be implemented using wire or cable, fiber optics, a phone line, a cellular phone link, a radio frequency link, and/or other communication channels. With such a communications interface, it is contemplated that the one or more processors 402 might receive information from a network or might output information to the network in the course of performing the above-described method steps. Furthermore, method embodiments may execute solely upon the processors or may execute over a network such as the Internet in conjunction with remote processors that shares a portion of the processing.

The term “non-transient computer readable medium” is used generally to refer to media such as main memory, secondary memory, removable storage, and storage devices, such as hard disks, flash memory, disk drive memory, CD-ROM, and other forms of persistent memory and shall not be construed to cover transitory subject matter, such as carrier waves or signals. Examples of computer code include machine code, such as produced by a compiler, and files containing higher level code that are executed by a computer using an interpreter. Computer readable media may also be computer code transmitted by a computer data signal embodied in a carrier wave and representing a sequence of instructions that are executable by a processor.

While this disclosure has been described in terms of several preferred embodiments, there are alterations, modifications, permutations, and various substitute equivalents, which fall within the scope of this disclosure. It should also be noted that there are many alternative ways of implementing the methods and apparatuses of the present disclosure. It is therefore intended that the following appended claims be interpreted as including all such alterations, modifications, permutations, and various substitute equivalents as fall within the true spirit and scope of the present disclosure.

What is claimed is:

1. A method for selectively etching a dielectric material with respect to a semiconductor material, the method comprising:
etching the dielectric material; and
passivating the semiconductor material, comprising providing a passivation gas comprising a non-thiol sulfur based component, wherein the non-thiol sulfur based component is oxygen free.

2. The method, as recited in claim 1, wherein the semiconductor material comprises at least one of silicon and germanium.

3. The method, as recited in claim 1, wherein the dielectric material comprises at least one of a silicon oxide based material and a silicon nitride based material.

4. The method, as recited in claim 1, further comprising forming the passivation gas into a plasma.

5. The method, as recited in claim 1, wherein the providing the passivation gas is simultaneous with etching the dielectric material.

6. The method, as recited in claim 1, wherein the providing the passivation gas is at a different time than etching the dielectric material, wherein the method comprises a plurality of cycles of etching the dielectric material and passivating the semiconductor material.

7. The method, as recited in claim 1, wherein the passivation gas comprises at least one of H₂S, CS₂, S(CH₃)₂, and C₂N₂S.

8. The method, as recited in claim 7, wherein the passivation gas further comprises at least one of H₂, N₂, a hydrocarbon, and a hydrofluorocarbon.

9. The method, as recited in claim 1, wherein the passivating the semiconductor material provides a passivation layer, the method further comprising removing the passivation layer.

10. The method, as recited in claim 1, wherein the dielectric material is below a metal containing mask, wherein the etching of the dielectric material selectively etches the dielectric material with respect to the metal containing mask and the semiconductor material.

11. The method, as recited in claim 10, wherein the providing the passivating the semiconductor material passivates the metal containing layer and the semiconductor material.

12. The method, as recited in claim 1, wherein the passivation gas comprises H₂S.

13. The method, as recited in claim 12, wherein the passivation gas further comprises at least one of H₂, N₂, a hydrocarbon, and a hydrofluorocarbon.

14. The method, as recited in claim 1, wherein the passivation gas further comprises at least one of H₂, N₂, a hydrocarbon, and a hydrofluorocarbon.
